(19) United States
(12) Patent Application Publication
(10) Pub. No.: US 2024/0312542 A1
(43) Pub. Date: Sep. 19, 2024

(54) SEMICONDUCTOR STORAGE DEVICE AND MEMORY SYSTEM

(71) Applicant: Kioxia Corporation, Tokyo (JP)

(72) Inventors: Masato ENDO, Yokohama Kanagawa (JP); Haruo MIKI, Yokohama Kanagawa (JP); Daiki SUGAWARA, Fujisawa Kanagawa (JP)

(73) Assignee: Kioxia Corporation, Tokyo (JP)

(21) Appl. No.: 18/591,856

(22) Filed: Feb. 29, 2024

(30) Foreign Application Priority Data
Mar. 17, 2023 (JP) 2023-043558

(51) Int. Cl. G11C 16/34; G11C 16/04; G11C 16/20

(52) U.S. Cl. CPC G11C 16/3495; G11C 16/0483; G11C 16/20

(57) ABSTRACT

A semiconductor storage device includes a thermal history monitor and a determination circuit. The thermal history monitor outputs a thermal history based on a characteristic variation of a memory cell when a reliability detection command is input from a controller or a host device. The determination circuit determines package reliability based on the thermal history output from the thermal history monitor.

### CROSS-REFERENCE TO RELATED APPLICATION

This application is based upon and claims the benefit of priority from Japanese Patent Application No. 2023-043558, filed Mar. 17, 2023, the entire contents of which are incorporated herein by reference.

### FIELD

Embodiments described herein relate generally to a semiconductor storage device and a memory system.

### BACKGROUND

As one type of semiconductor storage device, a NAND-type memory is known.

### DESCRIPTION OF THE DRAWINGS

FIG. 1 is a block diagram showing an example of a configuration of a memory system of a first embodiment.

FIG. 2 is a block diagram showing an example of the non-volatile memory in FIG. 1.

FIG. 3 is a diagram showing an example of a configuration of a block of a memory cell array having a three-dimensional structure.

FIG. 4 is a diagram showing an example of a relationship between a change in a threshold voltage distribution due to thermal stress and FBC.

FIG. 5 is a diagram showing an example of a relationship between the integrated time of thermal stress and FBC.

FIG. 6 is a diagram showing an example of a change in a threshold voltage distribution due to a threshold of a select gate and thermal stress.

FIG. 7 is a diagram showing an example of a change in a threshold voltage distribution when a variation amount of FBC is saturated due to being left for a long time.

FIG. 8 is a flowchart showing an example of a flow of a package reliability determination process.

FIG. 9 is a block diagram showing an example of a configuration of a memory system of a second embodiment.

FIG. 10 is a block diagram showing an example of the non-volatile memory in FIG. 9.

### DETAILED DESCRIPTION

Embodiments provide a semiconductor storage device and a memory system capable of detecting reliability of a package.

In general, according to one embodiment, the semiconductor storage device includes a thermal history monitor and a determination circuit. The thermal history monitor outputs a thermal history based on a characteristic variation of a memory cell when a reliability detection command is input from a controller or a host device. The determination circuit determines package reliability based on the thermal history output from the thermal history monitor.

Hereinafter, embodiments of the present disclosure will be described in detail with reference to the drawings.

### First Embodiment

### Configuration of Memory System

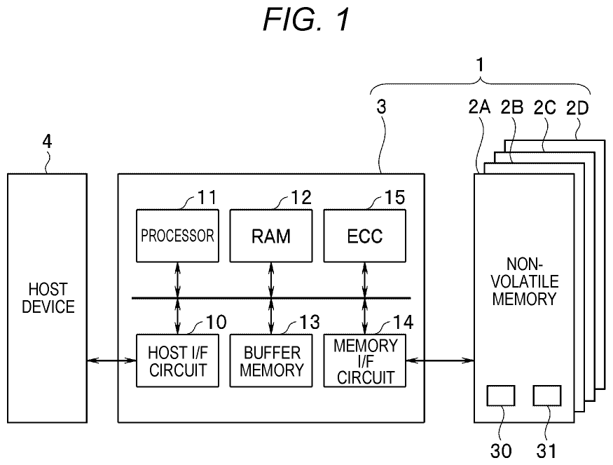

FIG. 1 is a block diagram showing an example of a configuration of a memory system of a first embodiment. A memory system 1 of the present embodiment includes a plurality of NAND-type non-volatile memories and a memory controller 3. FIG. 1 shows an example including four NAND-type non-volatile memories 2A to 2D. Hereinafter, when it is not necessary to distinguish the four NAND-type non-volatile memories 2A to 2D, the four NAND-type non-volatile 2A to 2D are collectively referred to as the NAND-type non-volatile memory 2. In addition, the NAND-type non-volatile memory is also simply referred to as a non-volatile memory. The memory system 1 reads, writes, and erases, etc., user data according to signals transmitted from a host device 4. The host device 4 is, for example, an electronic device such as a personal computer or a mobile terminal.

The memory system 1 may be implemented with a plurality of chips configuring the memory system 1 on a motherboard on which the host device 4 is mounted, or may be configured as a system large-scale integrated circuit (LSI) or a system-on-a-chip (SoC) in which the memory system 1 is achieved by one module. The memory system 1 is a system capable of storing user data, and is, for example, a memory card such as an SD card, a solid-state drive (SSD), or an embedded-multi-media card (eMMC).

The non-volatile memory 2 is a NAND-type memory including a plurality of memory cells, and stores data non-volatilely. The non-volatile memory 2 is an example of a semiconductor storage device. The non-volatile memory 2 includes a thermal history monitor 30 and a determination circuit 31. The reliability detection command is input to the non-volatile memory 2 from the memory controller 3 or the host device 4. When the reliability detection command is input, the thermal history is output from the thermal history monitor 30 to the determination circuit 31, and the determination circuit 31 determines the package reliability based on the thermal history. The non-volatile memory 2 outputs a determination result of the package reliability to the memory controller 3 or the host device 4. Other specific configurations of the non-volatile memory 2 will be described later.

The memory controller 3 issues an instruction to the non-volatile memory 2 to write (also referred to as program), read, erase, and the like in response to, for example, an instruction from the host device 4. The memory controller 3 manages a memory space of the non-volatile memory 2. The memory controller 3 includes a host interface (host I/F) circuit 10, a processor 11, a random access memory (RAM) 12, a buffer memory 13, a memory interface (memory I/F) circuit 14, an error checking and correcting (ECC) circuit 15, and the like.

The host I/F circuit 10 is connected to the host device 4 through a host bus and performs an interface process with the host device 4. The host I/F circuit 10 communicates an instruction, an address, and data to and from the host device 4.

The processor 11 is configured with, for example, a central processing unit (CPU). The processor 11 controls the operation of the entire memory controller 3. For example, when the write instruction is received from the host device 4, the processor 11 issues the write instruction in response to the write instruction from the host device 4 to the non-volatile memory 2 through the memory I/F circuit 14. The same applies to the case of reading and erasing. The processor 11 also executes various processes for managing the non-volatile memory 2, such as wear leveling.

The RAM 12 is used as a work region of the processor 11, and stores firmware data loaded from the non-volatile memory 2, various tables created by the processor 11, and the like. The RAM 12 is configured with, for example, a DRAM or an SRAM.

The buffer memory 13 temporarily stores the data transmitted from the host device 4 and temporarily stores the data transmitted from the non-volatile memory 2.

The memory I/F circuit 14 is connected to the non-volatile memory 2 via a bus and performs an interface process with the non-volatile memory 2. The memory I/F circuit 14 communicates an instruction, an address, and data to and from the non-volatile memory 2.

The ECC circuit 15 generates an error correction code for write data at the time of writing the data, and adds the error correction code to the write data to transmit the error correction code to the memory I/F circuit 14. In addition, the ECC circuit 15 performs error detection and/or error correction on the read data by using the error correction code included in the read data at the time of reading the data. The ECC circuit 15 may be provided in the memory I/F circuit 14.

### Configuration of Non-Volatile Memory

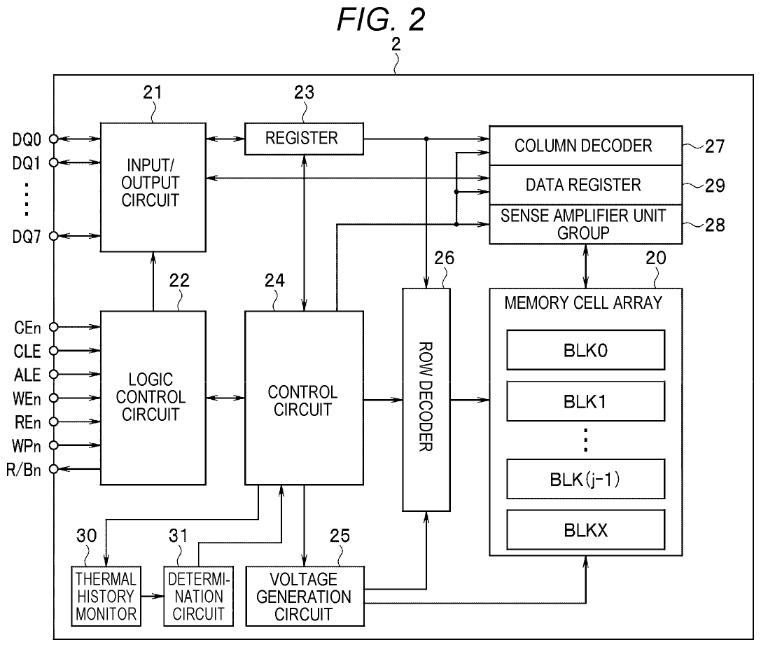

FIG. 2 is a block diagram showing an example of the non-volatile memory 2 in FIG. 1. The non-volatile memory 2 includes a memory cell array 20, an input/output circuit 21, a logic control circuit 22, a register 23, a control circuit 24, a voltage generation circuit 25, a row decoder 26, a column decoder 27, a sense amplifier unit group 28, and a data register (data cache) 29.

The memory cell array 20 includes j blocks BLK0 to BLK (j−1) and a block BLKX. j is an integer of 1 or more. Each of the plurality of blocks BLK includes a plurality of memory cell transistors. The memory cell transistor configures a memory cell configured to be electrically rewritten. A plurality of bit lines BL, a plurality of word lines WL, source line CELSRC, or the like are disposed in the memory cell array 20 to control the voltage applied to the memory cell transistor. The specific configuration of the block BLK will be described later.

The input/output circuit 21 and the logic control circuit 22 are connected to the memory controller 3 through a bus. The input/output circuit 21 communicates signals DQ (for example, DQ0 to DQ7) to and from the memory controller 3 through the bus.

The logic control circuit 22 receives an external control signal (for example, a chip enable signal CEn, a command latch enable signal CLE, an address latch enable signal ALE, a write enable signal WEn, a read enable signal REn, and a write protect signal WPn) from the memory controller 3 through the bus. The n assigned to the signal name indicates the active low. Also, the logic control circuit 22 transmits a ready/busy signal R/Bn to the memory controller 3 via the bus.

The signal CEn is a signal for selecting and enabling a specific non-volatile memory 2 in a system configuration in which a plurality of non-volatile memories 2 are used. The signal CLE enables commands transmitted as a signal DQ to be latched into the register 23. The signal ALE enables addresses transmitted as a signal DQ to be latched into the register 23. The signal WEn enables writing. The signal REn enables reading. The signal WPn prohibits writing and erasing. The signal R/Bn indicates whether the non-volatile memory 2 is in a ready state (a state in which the non-volatile memory 2 is able to accept an instruction from the outside) in which the non-volatile memory 2 does not perform a writing, reading, and erasing operation or in a busy state (a state in which the non-volatile memory 2 is not able to accept an instruction from the outside), when a basic operation command is used.

The register 23 includes a command register, an address register, a status register, and the like. The command register temporarily stores commands. The address register temporarily stores addresses. The status register temporarily stores data required for the operation of the non-volatile memory 2. The register 23 is configured with, for example, an SRAM.

The control circuit 24 receives a command from the register 23 and collectively controls the non-volatile memory 2 in accordance with the sequence based on this command.

The voltage generation circuit 25 receives a power supply voltage from the outside of the non-volatile memory 2 and generates a plurality of voltages required for a write operation, a read operation, and an erasing operation using the power supply voltage. The voltage generation circuit 25 supplies the generated plurality of voltages to the memory cell array 20, the row decoder 26, the sense amplifier unit group 28, and the like.

The row decoder 26 receives a row address from the register 23 and decodes the row address. The row decoder 26 performs a selection operation of a word line based on the decoded row address. A word line to which the memory cell transistor MT to be written and read is connected is referred to as a select word line. The row decoder 26 transfers a plurality of voltages required for the write operation, the read operation, and the erasing operation to the selected block BLK.

The column decoder 27 receives a column address from the register 23 and decodes the column address. The column decoder 27 supplies a predetermined voltage to each of the bit lines BL based on the decoded column address.

The sense amplifier unit group 28 detects and amplifies the data read from the memory cell transistor into the bit line at the time of reading the data. Further, the sense amplifier unit group 28 supplies the written data to the bit line BL at the time of writing the data.

The data register 29 temporarily stores the data transferred from the sense amplifier unit group 28 when the data is read, and serially transfers the data to the input/output circuit 21. In addition, the data register 29 temporarily stores the data serially transferred from the input/output circuit 21 at the time of writing the data, and transfers the data to the sense amplifier unit group 28. The data register 29 is configured with an SRAM or the like.

The thermal history monitor 30 outputs the thermal history to the determination circuit 31 based on the control of the control circuit 24. The control circuit 24 issues an instruction to the thermal history monitor 30 to output the thermal history when the reliability detection command is input from the memory controller 3 or the host device 4.

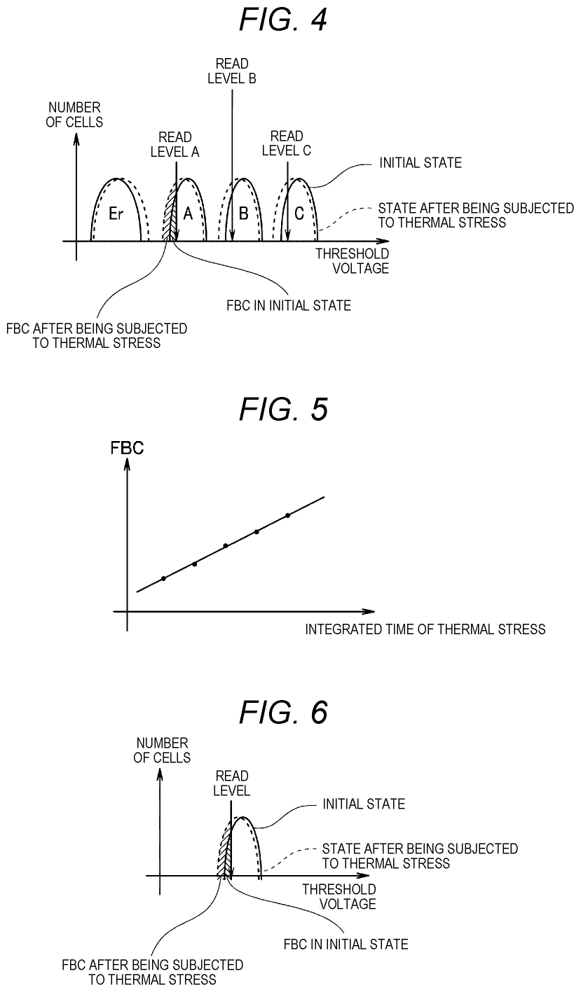

As an index of the thermal history, the characteristic variation of the memory cell is used. Specifically, as the index of the thermal history, fail bit count (FBC) at a certain read level is used. The FBC is the number of bits that are not possible to reach the certain read level. The FBC will be described with reference to FIGS. 4 and 5 to be described later.

The determination circuit 31 determines whether the thermal history input from the thermal history monitor 30 is equal to or higher than the allowable value of the package reliability. The determination circuit 31 outputs an alarm when the thermal history is equal to or higher than the allowable value of the package reliability. On the other hand, the determination circuit 31 ends the reliability detection (evaluation of the thermal history) when the thermal history is less than the allowable value of the package reliability. The determination circuit 31 may output a usage proportion with respect to the package reliability when the thermal history is less than the allowable value of the package reliability.

The control circuit 24 outputs the determination result determined by the determination circuit 31 to the memory controller 3 or the host device 4. An execution cycle of the determination of the package reliability may be changed depending on the environment in which the memory system 1 is used. For example, when the memory system 1 is used in an environment in which the memory system 1 is excessively affected by heat, the execution cycle of the package reliability determination is shortened. On the other hand, when the memory system 1 is used in an environment in which the memory system 1 is not excessively affected by heat, the execution cycle of the determination of the package reliability is lengthened.

### Block Configuration of Memory Cell Array

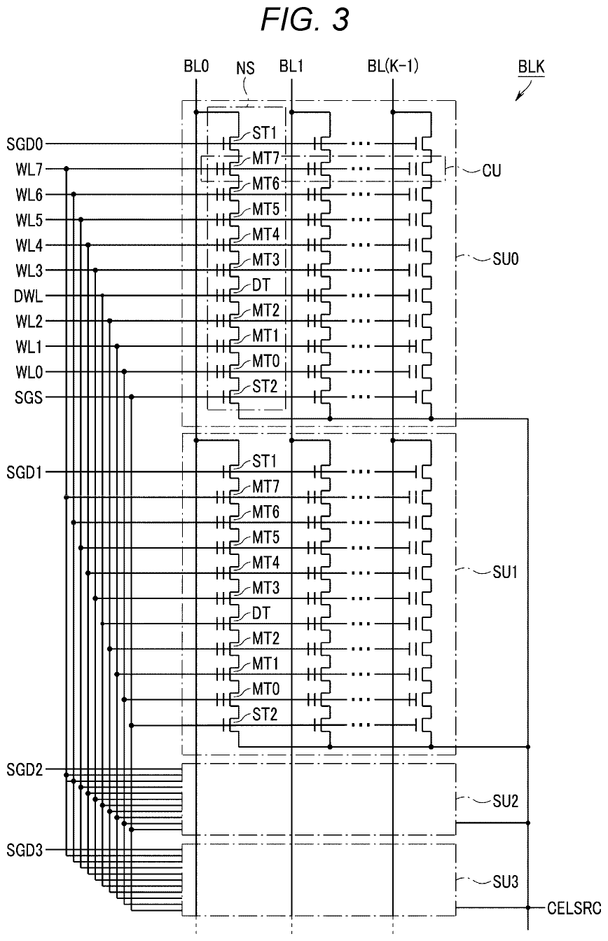

FIG. 3 is a diagram showing an example of a configuration of a block of a memory cell array 20 having a three-dimensional structure. FIG. 3 shows one block BLK of a plurality of blocks configuring the memory cell array 20. The other blocks of the memory cell array also have the same configuration as in FIG. 3.

As shown, the block BLK includes, for example, four string units SU0 to SU3 (hereinafter, these are collectively referred to as the string unit SU). In addition, each of the string units SU has a NAND string NS including a plurality of memory cell transistors MT (MT0 to MT7), one dummy cell transistor DT, and select gate transistors ST1 and ST2. The number of memory cell transistors MT provided in the NAND string NS is set to 8 in FIG. 3, but may be further increased. The select gate transistors ST1 and ST2 are shown as one transistor in the electrical circuit, but may be the same as the memory cell transistor in the structure. In addition, a plurality of select gate transistors may be used as the select gate transistors ST1 and ST2, respectively. Furthermore, dummy cell transistors may be provided between the memory cell transistors MT and the select gate transistors ST1 and ST2.

The memory cell transistors MT are connected in series between the select gate transistors ST1 and ST2. The memory cell transistor MT7 on one end side (bit line side) is connected to the select gate transistor ST1, and the memory cell transistor MT0 on the other end side (source line side) is connected to the select gate transistor ST2.

The dummy cell transistor DT has the same structure as the memory cell transistor MT, but is not used to store the data transmitted from the memory controller 3 in response to a request from the host device 4.

In the example of FIG. 3, the dummy cell transistor DT is disposed (connected in series) between the memory cell transistors MT2 and MT3, but the present disclosure is not limited thereto, and the dummy cell transistor DT may be disposed (connected in series) between the select transistor ST2 and the memory cell transistor MT0, between the memory cell transistor MT7 and the select transistor ST1, or between any two memory cell transistors MT among the memory cell transistors MT0 to MT7.

The gate of select gate transistor ST1 of each of the string units SU0 to SU3 is connected to each of the select gate lines SGD0 to SGD3 (hereinafter, referred to as the select gate line SGD in representative of these). In addition, the gate of each select gate transistor ST2 of the string units SU0 to SU3 is connected to each of the select gate lines SGS0 to SGS3 (hereinafter, referred to as the select gate line SGS in representative of these). The gates of the plurality of select gate transistors ST2 in each block BLK may be connected to a common select gate line SGS.

The gates of the memory cell transistors MT0 to MT7 in the identical block BLK are commonly connected to word lines WL0 to WL7, respectively. Similarly, the control gates of the dummy cell transistors DT in the identical block BLK are commonly connected to the dummy word line DWL. That is, the word lines WL0 to WL7 and the dummy word lines DWL are commonly connected between the plurality of string units SU0 to SU3 in the identical block BLK, whereas the select gate lines SGD are independent for each of the string units SU0 to SU3 even in the identical block BLK. The gates of the memory cell transistors MTi in the same row in the block BLK are connected to the identical word line WLi.

Each NAND string NS is connected to a corresponding bit line. Therefore, each memory cell transistor MT is connected to the bit line via the select gate transistors ST1 and ST2 provided in the NAND string NS and other memory cell transistors MT. In general, data of the memory cell transistors MT in the identical block BLK is collectively erased. On the other hand, typically, data reading and writing are collectively performed on a plurality of memory cell transistors MT commonly connected to one word line WL disposed in one string unit SU. Such a set of memory cell transistors MT sharing the word line WL in one string unit SU is referred to as a cell unit CU.

The write operation to the cell unit CU is performed in units of pages. For example, when each cell is a triple level cell (TLC) capable of storing 3 bits (8 values) of data, one cell unit CU may store data of 3 pages. The 3 bits that may be stored by each memory cell transistor MT correspond to the 3 pages, respectively.

### Relationship Between Change in Threshold Voltage Distribution and FBC

FIG. 4 is a diagram showing an example of a relationship between a change in a threshold voltage distribution due to thermal stress and FBC.

FIG. 4 shows an example of a threshold voltage distribution of the non-volatile memory 2 of 2 bit/cell. In the non-volatile memory 2, information is stored by the charge amount accumulated in the charge storage layer of the memory cell. Each memory cell has a threshold voltage corresponding to the charge amount. Then, the plurality of data values stored in the memory cell are respectively associated with the plurality of regions (threshold voltage distribution regions) of the threshold voltage.

The four distributions (mountain type) indicated by Er, A, B, and C in FIG. 4 indicate four threshold voltage distribution regions. As described above, each memory cell has distribution a threshold voltage partitioned by three boundaries. In FIG. 4, the horizontal axis indicates the threshold voltage, and the vertical axis indicates the distribution of the memory bits (the number of bits).

In addition, in FIG. 4, the four threshold voltage distributions indicated by solid lines indicate the threshold voltage distributions in the initial state, and the four threshold voltage distributions indicated by broken lines indicate the threshold voltage distributions after being subjected to the thermal stress. That is, when the threshold voltage distribution in the initial state is indicated by a solid line, the threshold voltage distribution after being subjected to the thermal stress varies as a broken line.

Therefore, for example, the number of bits (that is, the FBC, which is indicated by the oblique line in FIG. 4) that do not reach the read level A increases in the FBC after being subjected to the thermal stress as compared to the FBC in the initial state.

FIG. 5 is a diagram showing an example of a relationship between the integrated time of the thermal stress and the FBC. FIG. 5 shows a relationship between the integrated time of the thermal stress and the FBC when the thermal stress is actually applied to the memory cell.

As shown in FIG. 5, the increase in FBC has a correlation with the integrated time of the thermal stress. Specifically, when the time for applying the thermal stress is long, the FBC also increases in proportion thereto. Therefore, the thermal history monitor 30 is able to monitor the integration of the thermal history from the increase amount of the FBC.

In the present embodiment, in order to use the characteristic variation of such a memory cell as an index of the thermal history received by the package, first, the thermal history monitor 30 is initialized, and the initial state of the memory cell is recorded. Specifically, the memory cell is initialized in a manufacturing step up to a multi-chip package (MCP), and the FBC in the initial state is recorded in the determination circuit 31. The initial state may be a data pattern in which the memory cell is fixed to a certain threshold, or may be a data pattern having regularity.

In the product assembly step after the manufacturing step up to the MCP, when the characteristic variation of the memory cell due to the thermal stress is not able to be ignored, the initialization of the memory cell may be performed in the product assembly step.

In addition, the correlation between the thermal history allowed as the package reliability and the variation amount of the FBC is acquired before the determination by the determination circuit 31, and the variation amount of the FBC that is allowable as the package reliability is recorded in the determination circuit 31.

The determination circuit 31 determines the package reliability by comparing the initial state of the memory cell recorded at the time of performing the initialization of the thermal history monitor 30 and the variation amount in the FBC that is allowable as the package reliability recorded before the determination by the determination circuit 31, with the thermal history from the thermal history monitor 30.

In the present embodiment, the FBC of the memory cell is described as an example as the index of the thermal history, but the present disclosure is not limited thereto. For example, the package reliability be determined from may the characteristic variation of the select gate or the dummy gate, the FBC using the threshold of the select gate or the threshold of the dummy gate, or the difference or the magnitude of the variation in the FBCs.

FIG. 6 is a diagram showing an example of a change in a threshold voltage distribution due to a threshold of a select gate and thermal stress. In FIG. 6, the threshold voltage distribution in the initial state is indicated by a solid line, and the threshold voltage distribution after being subjected to the thermal stress is indicated by a broken line.

The threshold voltage distribution changes due to the application of the thermal stress, and thus the number of bits that do not reach a certain read level increases. Therefore, the determination circuit 31 monitors the integrated amount of the thermal history using the variation amount of the FBC.

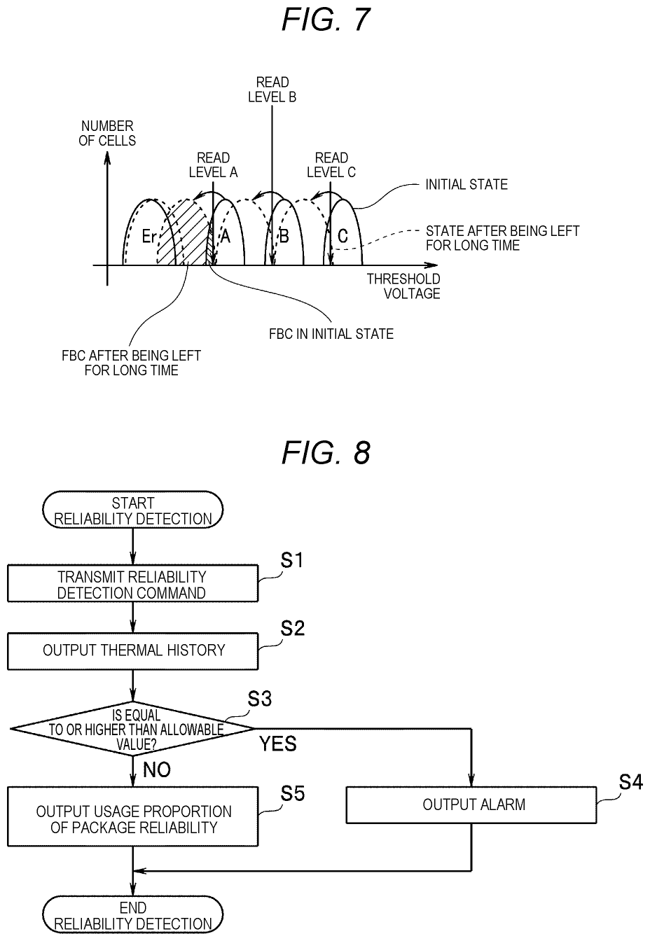

Furthermore, linearity of the characteristic variation of the memory cell may be lost due to being left for a long time or the like. That is, the correlation between the integrated time of the thermal stress and the increase in the FBC as shown in FIG. 5 may not be obtained. FIG. 7 is a diagram showing an example of a change in the threshold voltage distribution when the variation amount of FBC is saturated due to being left for a long time.

When the variation amount of the FBC is saturated due to being left for a long time, the linearity of the characteristic variation of the memory cell is lost, and thus it is not possible to correctly evaluate the applied thermal history by monitoring the characteristic variation of the memory cell. Therefore, in order to bring the memory cell into a state in which the characteristic variation of the memory cell is able to be detected again by the thermal history, it is necessary to initialize the memory cell.

Specifically, the determination of the initialization of the memory cell is determined by whether the FBC reached the initialization criterion. The initialization criterion of the FBC evaluate, in advance, the FBC in which the linearity of the variation of the FBC with respect to the thermal history is lost in evaluating the variation characteristic of the FBC with respect to the thermal history of the non-volatile memory 2 including the thermal history monitor 30. In the determination of the package reliability accompanied by the initialization of the memory cell, first, the number of times of initialization is stored in the non-volatile memory 2 (or the memory controller 3). Next, the data of the memory cell is initialized to return to the initial state. Then, the variation amount of the FBC is measured again in the thermal history monitor 30. The determination circuit 31 determines whether the package reliability is equal to or higher than the allowable value, based on the number of times of initialization and the FBC from the thermal history monitor 30.

In addition, when the memory cell is initialized, the criterion of the FBC to be initialized is set to, for example, X. When the FBC exceeds X at this time, in a case where the initialization is performed, the number of times of initialization is stored.

Alternatively, at the time of initialization, the X pieces may be initialized to 50%, that is, 0.5X. Meanwhile, it may also initialize at any ratio. When the criteria for initialization are different as described above, not only the number of times of initialization but also the number of FBCs may be recorded.

When the first initialization is performed at 0.5× and the second initialization is performed at 0.7×, the initialization is performed twice, and the number of FBCs is integrated and stored as 1.2×. Alternatively, the number of FBCs may be stored for each number of times, such as storing the number of FBCs as 0.5× for the first time and then 0.7× for the second time.

Alternatively, the initialization criteria may not be held, and the initialization may be performed at any time. At this time, the number of times of initialization and the number of FBCs may be recorded. The number of FBCs may be integrated each time of initialization and may be stored.

The determination circuit 31 may use the stored number of FBCs for the determination.

Furthermore, in the present embodiment, the configuration is provided with the non-volatile memories 2A to 2D and the memory controller 3 connected to the host device 4, but the present disclosure is not limited to this. For example, a configuration may be adopted in which the memory controller 3 is not provided and the host device 4 and the non-volatile memories 2A to 2D are directly connected.

### Package Reliability Determination Process

FIG. 8 is a flowchart showing an example of a flow of a package reliability determination process.

First, the reliability detection command is transmitted from the memory controller 3 or the host device 4 to the non-volatile memory 2 (S1). The reliability detection command is input to the control circuit 24 through the input/output circuit 21 and the register 23. The control circuit 24 instructs the thermal history monitor 30 to output the thermal history when the reliability detection command is input.

Next, the thermal history monitor 30 outputs the thermal history to the determination circuit 31 based on the instruction of the control circuit 24 (S2). The thermal history is the number of bits that are not possible to reach a certain read level, that is, the FBC, as described above.

Next, the determination circuit 31 determines whether the thermal history from the thermal history monitor 30 is equal to or higher than the allowable value of the package reliability (S3). When the determination circuit 31 determines that the thermal history is equal to or higher than the allowable value of the package reliability (S3: YES), the determination circuit 31 outputs an alarm (S4) and ends the process.

On the other hand, when the determination circuit 31 determines that the thermal history is not equal to or higher than the allowable value of the package reliability (less than the allowable value) (S3: NO), the determination circuit 31 outputs the usage proportion of the package reliability (S5) and ends the process.

The control circuit 24 transmits the alarm or the usage proportion of the package reliability output from the determination circuit 31 to the memory controller 3 or the host device 4 to which the reliability detection is command transmitted.

As described above, the non-volatile memory 2 improves the data safety by determining the package reliability from the integrated amount of heat received by the package using the thermal history according to the characteristic variation of the memory cell.

### Second Embodiment

Next, a second embodiment will be described.

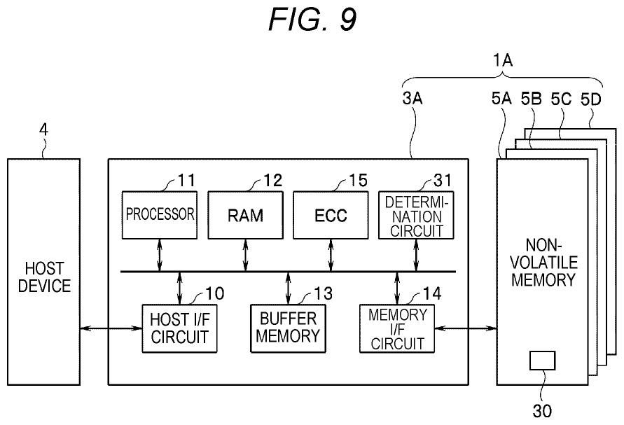

FIG. 9 is a block diagram showing an example of a configuration of a memory system of the second embodiment. In FIG. 9, the same components as those in FIG. 1 are denoted by the same reference numerals, and the description thereof will be omitted.

A memory system 1A of the present embodiment includes a memory controller 3A and NAND-type non-volatile memories 5A to 5D. Hereinafter, when it is not necessary to distinguish the four NAND-type non-volatile memories 5A to 5D, the four NAND-type non-volatile memories 5A to 5D are collectively referred to as the NAND-type non-volatile memory 5. In addition, the NAND-type non-volatile memory is also simply referred to as a non-volatile memory.

The non-volatile memory 5 includes the thermal history monitor 30. The memory controller 3A includes the determination circuit 31 in addition to the memory controller 3 in FIG. 1.

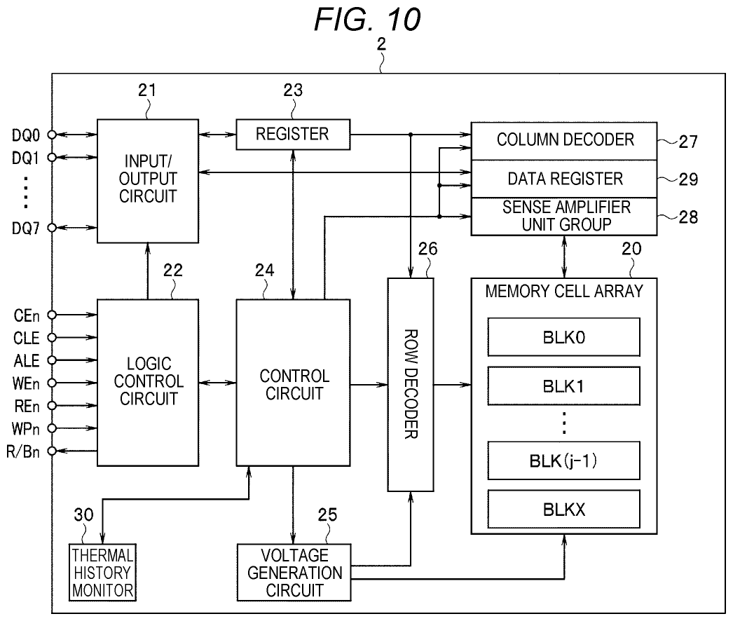

FIG. 10 is a block diagram showing an example of the non-volatile memory 5 in FIG. 9. In FIG. 10, the same components as those in FIG. 2 are denoted by the same reference numerals, and the description thereof will be omitted.

As shown in FIG. 10, the non-volatile memory 5 is the non-volatile memory 2 of FIG. 2 from which the determination circuit 31 is deleted.

The control circuit 24 is input with the reliability detection command from the memory controller 3 or the host device 4 through the input/output circuit 21 and the register 23.

When the reliability detection command is input, the control circuit 24 receives the thermal history in response to the characteristic variation of the memory cell from the thermal history monitor 30 and outputs the thermal history to the memory controller 3A through the register 23 and the input/output circuit 21.

The thermal history input to the memory controller 3A is input to the determination circuit 31. The determination circuit 31 determines whether the input thermal history is equal to or higher than the allowable value of the package reliability. In addition, when a plurality of non-volatile memories 5 are provided as in the present embodiment, the determination circuit 31 averages the thermal history input from the plurality of non-volatile memories 5 and determines whether the averaged thermal history is equal to or higher than the allowable value of the package reliability. In this way, the package reliability can be reduced to vary by averaging the input thermal history and determining the package reliability.

For example, in the first embodiment, since each of the non-volatile memories 2 includes the determination circuit 31, an alarm is output when the non-volatile memory 2 having extremely poor package reliability is provided.

On the other hand, in the present embodiment, even when the non-volatile memory 5 having extremely poor package reliability is provided, the package reliability is determined including information on the thermal history of other non-volatile memories. As described above, the memory system 1A can lengthen the lifetime of the package as a whole compared to the memory system 1 of the first embodiment by averaging the thermal history and determining the package reliability of the non-volatile memory 5.

In addition, by providing the determination circuit 31 in the memory controller 3A, each of the non-volatile memories 5A to 5D does not need to include the determination circuit. Therefore, the non-volatile memory 5 can reduce a circuit area and a cost more than the non-volatile memory 2 of the first embodiment.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a thermal history monitor configured to output a thermal history based on a characteristic variation of a memory cell when a reliability detection command is input from a controller or a host device; and
a determination circuit configured to determine package reliability based on the thermal history output from the thermal history monitor.

2. The semiconductor storage device according to claim 1, wherein
the determination circuit is configured to determine whether the thermal history is equal to or higher than an allowable value of the package reliability, and output an alarm when the thermal history is equal to or higher than the allowable value.

3. The semiconductor storage device according to claim 1, wherein
the thermal history is a fail bit count (FBC) at a predetermined read level.

4. The semiconductor storage device according to claim 1, wherein
the thermal history monitor is configured to output the thermal history based on a characteristic variation of a select gate or a dummy gate.

5. The semiconductor storage device according to claim 1, wherein
the determination circuit is configured to initialize data of the memory cell and store the number of times of initialization when linearity of the characteristic variation of the memory cell is not obtained.

6. A memory system comprising:
a controller; and
a semiconductor storage device that stores data based on control of the controller,
wherein the semiconductor storage device has a thermal history monitor configured to output a thermal history based on a characteristic variation of a memory cell when a reliability detection command is input from the controller or a host device, and
the controller has a determination circuit configured to determine package reliability based on the thermal history output from the thermal history monitor.

7. The memory system according to claim 6, wherein
the determination circuit is configured to determine whether the thermal history is equal to or higher than an allowable value of the package reliability, and output an alarm when the thermal history is equal to or higher than the allowable value.

8. The memory system according to claim 6, wherein
the thermal history is a fail bit count (FBC) at a predetermined read level.

9. The memory system according to claim 6, wherein
the thermal history monitor is configured to output the thermal history based on a characteristic variation of a select gate or a dummy gate.

10. The memory system according to claim 6, wherein
the determination circuit is configured to initialize data of the memory cell and store the number of times of initialization when linearity of the characteristic variation of the memory cell is not obtained.

11. A method, comprising:
outputting a thermal history based on a characteristic variation of a memory cell when a reliability detection command is input from a controller or a host device; and
determining package reliability based on the output thermal history.

12. The method according to claim 11, further comprising
determining whether the thermal history is equal to or higher than an allowable value of the package reliability, and outputting an alarm when the thermal history is equal to or higher than the allowable value.

13. The method according to claim 11, wherein
the thermal history is a fail bit count (FBC) at a predetermined read level.

14. The method according to claim 11, wherein
the thermal history is output based on a characteristic variation of a select gate or a dummy gate.

15. The method according to claim 11, further comprising
initializing data of the memory cell and storing the number of times of initialization when linearity of the characteristic variation of the memory cell is not obtained.
